(19) United States
(12) Patent Application Publication
(10) Pub. No.: US 2026/0239970 A1
(43) Pub. Date: Aug. 13, 2026

(54) ELECTRONIC PACKAGE

(71) Applicant: SILICONWARE PRECISION INDUSTRIES CO., LTD., Taichung City (TW)

(72) Inventors: Tsung-Li LIN, Taichung City (TW); Chun-Lin TSAI, Taichung City (TW)

(73) Assignee: SILICONWARE PRECISION INDUSTRIES CO., LTD., Taichung City (TW)

(21) Appl. No.: 19/428,089

(22) Filed: Dec. 19, 2025

(30) Foreign Application Priority Data
Feb. 7, 2025 (TW) 114104605

(51) Int. Cl. H10W 40/25; H10W 40/20; H10W 40/22; H10W 70/63; H10W 90/00

(52) U.S. Cl. CPC H10W 40/258; H10W 40/22; H10W 40/233; H10W 70/63; H10W 40/242; H10W 90/724; H10W 90/736

(57) ABSTRACT

Provided is an electronic package, including: a carrier, an electronic element and a heat dissipating accelerator disposed on the carrier, and a heat dissipating member disposed on the electronic element. Heat generated from the electronic element during operating is transferred outward not only via the heat dissipating member, but also the carrier and the heat dissipating accelerator to meet the high demand of heat dissipation.

### BACKGROUND

### 1. Technical Field

The present disclosure relates to a semiconductor package, and more particularly, to an electronic package having a heat dissipating structure.

### 2. Description of Related Art

In high demand of functionality and processing speed of electronic products, semiconductor chips as the core components of electronic products may be configured with electronic elements and electronic circuits in higher density. Therefore, a greater amount of heats are generated by the semiconductor chips during operation.

In order to rapidly dissipate heat outward, a heat dissipating sheet is generally configured on a semiconductor package in the industry. The heat dissipating sheet is generally bonded to the back surface of the semiconductor chip via, for example, a thermal interface material (TIM), and heat generated from the semiconductor chip can be dissipated via the thermal interface material and the heat dissipating sheet.

As shown in FIG. 1, a conventional manufacturing method of a semiconductor package 1 is provided. A semiconductor chip 11 is firstly disposed on a package substrate 10 with an active surface 11a of the semiconductor chip 11 in a flip chip manner (i.e. via conductive bumps 110 and underfill 111), a heat dissipating member 13 is then bonded to an inactive surface 11b of the semiconductor chip 11 with a top sheet 130 of the heat dissipating member 13 via a thermal-conductive body 12, and supporting feet 131 of the heat dissipating member 13 is disposed on the package substrate 10 via an adhesive layer 14. In operation, heats generated from the semiconductor chip 11 are transferred via the inactive surface 11b, the thermal-conductive body 12, and the top sheet 130 of the heat dissipating member 13, and is dissipated to external of the semiconductor package 1.

However, with more and more demand for functionality of the semiconductor chip 11, the number of I/O thereof is increasing, simultaneously heats generated are higher and higher, and the aforementioned heat dissipating member 13 has not met high demand of heat dissipation for present electronic products.

Therefore, how to overcome the aforementioned problems of the prior art has become an urgent issue to be resolved.

### SUMMARY

In view of the aforementioned shortcomings of the prior art, the present disclosure provides an electronic package, which comprises: a carrier having a first side and a second side opposite to the first side and including an insulating layer and a metallic layer encapsulated by the insulating layer, an electronic element disposed on the first side of the carrier and electrically connected to the carrier, a heat dissipating accelerator disposed on the first side of the carrier and thermally connected to the metallic layer of the carrier, and a heat dissipating member disposed on the electronic element.

In the aforementioned electronic package, the carrier is a substrate with a core layer or a coreless substrate.

In the aforementioned electronic package, the metallic layer includes a plurality of traces and a plurality of conductive holes connected to the plurality of traces, wherein a part of the plurality of conductive holes are conductive blind holes and the other part of the plurality of conductive holes are thermal-conductive blind holes.

In the aforementioned electronic package, the electronic element has an active surface and an inactive surface opposite to the active surface, the active surface includes a plurality of electrode pads allowing the electronic element to be disposed on the first side of the carrier with the active surface thereof via a plurality of conductive bumps.

In the aforementioned electronic package, the heat dissipating accelerator is a ring shape and surrounds a periphery of the electronic element.

In the aforementioned electronic package, the heat dissipating accelerator is thermally connected to the metallic layer of the carrier via thermal-conductive glue.

In the aforementioned electronic package, the heat dissipating member includes a body portion and a supporting portion extending outward from the body portion. The body portion is disposed on the electronic element via a thermal interface material, and the supporting portion is bonded to the first side of the carrier and surrounds the electronic element.

In the aforementioned electronic package, the body portion of the heat dissipating member is formed with a heat dissipating hole, and a position of the heat dissipating hole of the heat dissipating member is corresponded with a position of the heat dissipating accelerator.

The aforementioned electronic package, further comprises a plurality of conductive elements configured on the second side of the carrier.

Therefore, in the electronic package according to the present disclosure, a heat dissipating accelerator is disposed on a carrier carrying an electronic element, a heat dissipating member is simultaneously disposed on the electronic element, thereby transferring heats generated from the electronic element during operating outward not only via the heat dissipating member but also the carrier and the heat dissipating accelerator to significantly enhance the heat dissipating efficiency of the electronic package by multiple heat transferring paths.

### BRIEF DESCRIPTION OF THE DRAWINGS

FIG. 1 is a schematic cross-sectional view of a conventional semiconductor package.

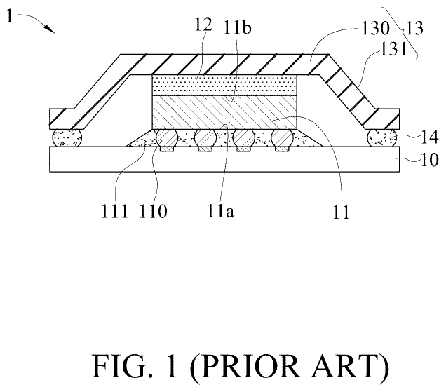

FIG. 2 is a schematic cross-sectional view of an electronic package according to the present disclosure.

FIG. 3 is a partial schematic top view of an electronic package corresponding to an electronic element according to the present disclosure.

FIG. 4 is a partial schematic top view of an electronic package corresponding to an electronic element of another embodiment according to the present disclosure.

FIG. 5 is a partial schematic top view of an electronic package corresponding to a heat dissipating member according to the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

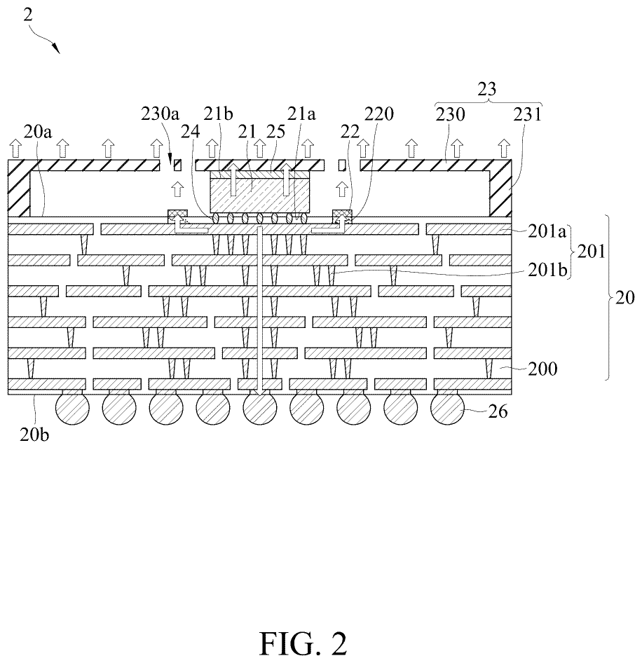

Please refer to FIG. 2, which is a schematic cross-sectional view of an electronic package 2 according to the present disclosure. The electronic package 2 comprises a carrier 20, an electronic element 21 disposed on the carrier 20, a heat dissipating accelerator 22 disposed on the carrier 20, and a heat dissipating member 23 disposed on the electronic element 21.

The carrier 20 is, for example, a substrate with a core layer or without a core layer (coreless), which includes an insulating layer 200 and a metallic layer 201 encapsulated by the insulating layer and has a first side 20a and a second side 20b opposite to the first side 20a. Also, the insulating layer 200 is made of a dielectric material such as polybenzoxazole (PBO), polyimide (PI), prepreg (PP), and the likes. The metallic layer 201 is made of copper.

The metallic layer 201 includes a plurality of traces 201a and a plurality of conductive holes 201b connected to the plurality of traces 201a, wherein a part of the plurality of conductive holes 201b are served as conductive blind holes for transmitting electronic signals, and the other part of the plurality of conductive holes 201b are served as thermal-conductive blind holes of heat dissipating paths

The electronic element 21 is disposed on the first side 20a of the carrier 20 and is electrically connected to the carrier 20. In an embodiment, the electronic element 21 is disposed on the first side 20a of the carrier 20 via a plurality of conductive bumps 24 and is electrically connected to the metallic layer 201 (trace 201a) of the carrier 20. The electronic element 21 is an active element, a passive element, or a combination thereof, the active element is, for example, a semiconductor chip, and the passive element is, for example, a resistor, a capacitor, and an inductor. For example, the electronic element 21 is a semiconductor chip, which has an active surface 21a and an inactive surface 21b opposite to the active surface 21a, and the active surface 21a of the electronic element 21 includes a plurality of electrode pads. The electronic element 21 is disposed on the first side 20a of the carrier 20 with the active surface 21a thereof in a flip chip manner and is electrically connected to the carrier 20 via a plurality of conductive bumps 24 such as soldering materials, metallic pillars, and the likes.

Electronic signals of the electronic element 21 may be transmitted outward via a part of the conductive holes 201b (the conductive blind holes), and heats generated from the electronic element 21 during operating may be transferred outward via the other part of the conductive holes 201b (the thermal-conductive blind holes) of the carrier 20 (as arrows shown in FIG. 2).

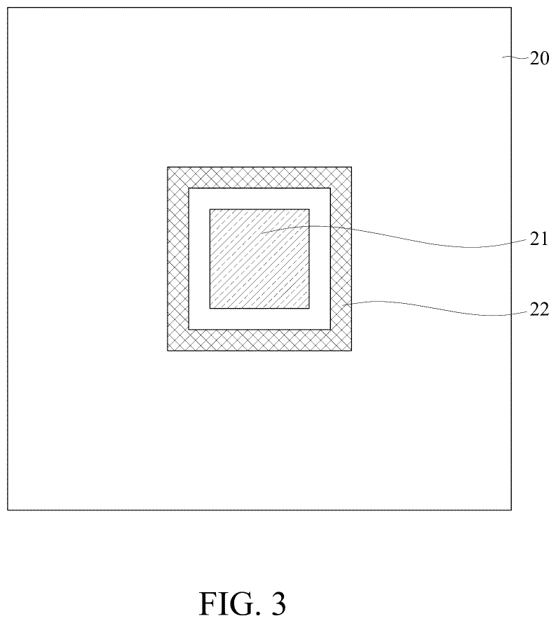

Referring to FIG. 3, which is a partial schematic top view of an electronic package 2 corresponding to an electronic element 21 according to the present disclosure. The heat dissipating accelerator 22 is disposed on the first side 20a of the carrier 20. In an embodiment, the heat dissipating accelerator 22 is, for example, in a ring shape and surrounds the periphery of the electronic element 21, being made of metal or high thermal-conductive materials and being thermally connected to the metallic layer 201 of the carrier 20 via thermal-conductive glue. Heats generated from the carrier 20 may be rapidly dissipated (as arrows shown in FIG. 3) via the heat dissipating accelerator 22.

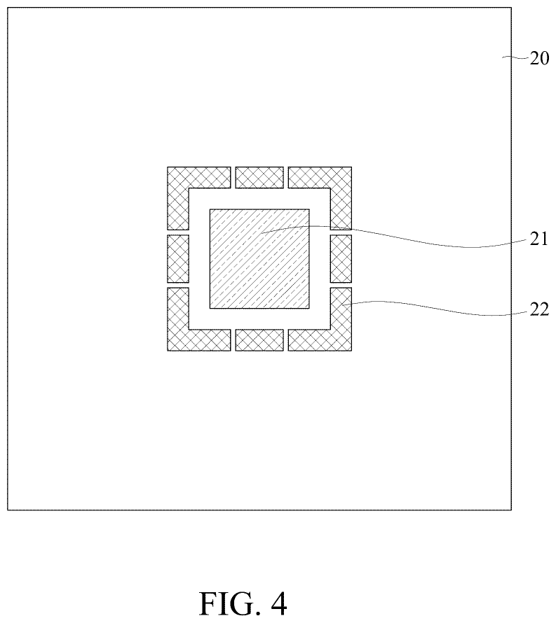

Please refer to FIG. 4, in another embodiment, the heat dissipating accelerator 22 is a plurality of blocks surrounding the periphery of the electronic element 21. It should be understood that the shape of the heat dissipating accelerator 22 may be varied with demand of realistic design, but is not limited to the aforementioned examples.

The heat dissipating member 23 is in a lid shape and includes a body portion 230 and a supporting portion 231 extending outward from the body portion 230, the body portion 230 is disposed on an inactive surface 21b of the electronic element 21 via a thermal interface material 25, and heats generated from the electronic element 21 during operating can be transferred to external (as arrows shown in FIG. 4) via the thermal interface material 25 and the heat dissipating member 23. The supporting portion 231 is, for example, in a ring or a pillar shape, being bonded to the first side 20a of the carrier 20 via an adhesive layer and surrounding the electronic element 21.

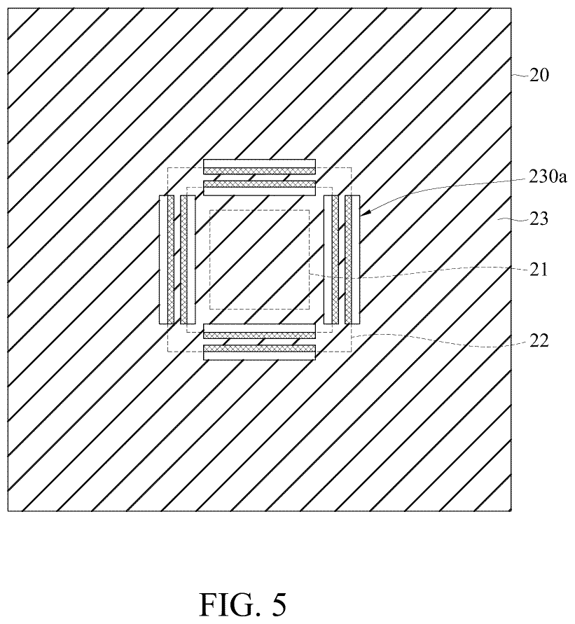

Referring to FIG. 5, which is a partial schematic top view of an electronic package 2 corresponding to a heat dissipating member 23 according to the present disclosure. A heat dissipating hole 230a can be further formed at the body portion 230 of the heat dissipating member 23, and a position of the heat dissipating hole 230a is corresponded with a position of the heat dissipating accelerator 22, thereby enhancing heat dissipating efficiency. In one embodiment, the distribution area (width) of the heat dissipating hole 230a is larger than the distribution area (width) of the heat dissipating accelerator 22, thereby being effective for thermal conductivity. In one embodiment, the heat dissipating hole 230a is, for example, in a shape of a plurality of trenches and is correspondingly configured above the heat dissipating accelerator 22. It should be understood that the shape of the heat dissipating hole 230a can be varied with demand of realistic design, but is not limited to the aforementioned examples.

Further, a plurality of conductive elements 26 can be disposed on the second side 20b of the carrier 20, a part of the plurality of conductive element 26 can be used to transmit electronic signals to an external device, and the other part of the plurality of conductive elements 26 can be used to transfer heats to external, thereby enhancing heat dissipating efficiency. The conductive element 26 is, for example, a solder bump.

To sum up, in the electronic package according to the present disclosure, a heat dissipating accelerator is disposed on a carrier carrying an electronic element, a heat dissipating member is simultaneously disposed on the electronic element, thereby transferring heats generated from the electronic element during operating outward not only via the heat dissipating member but also the carrier and the heat dissipating accelerator to significantly enhance the heat dissipating efficiency of the electronic package by multiple heat transferring paths.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier having a first side and a second side opposite to the first side and including an insulating layer and a metallic layer encapsulated by the insulating layer;
an electronic element disposed on the first side of the carrier and electrically connected to the carrier;
an heat dissipating accelerator disposed on the first side of the carrier and thermally connected to the metallic layer of the carrier; and
a heat dissipating member disposed on the electronic element.

2. The electronic package of claim 1, wherein the carrier is a substrate with a core layer or a coreless substrate.

3. The electronic package of claim 1, wherein the metallic layer comprises a plurality of traces and a plurality of conductive holes connected to the plurality of traces.

4. The electronic package of claim 3, wherein a part of conductive holes are conductive blind holes and the other part of conductive holes are thermal-conductive blind holes.

5. The electronic package of claim 1, wherein the electronic element has an active surface and an inactive surface opposite to the active surface, the active surface includes a plurality of electrode pads, allowing the electronic element to be disposed on the first side of the carrier with the active surface thereof via a plurality of conductive bumps.

6. The electronic package of claim 1, wherein the heat dissipating accelerator is in a ring shape and surrounds a periphery of the electronic element.

7. The electronic package of claim 1, wherein the heat dissipating accelerator is thermally connected to the metallic layer of the carrier via thermal-conductive glue.

8. The electronic package of claim 1, wherein the heat dissipating member includes a body portion and a supporting portion extending outward from the body portion.

9. The electronic package of claim 8, wherein the body portion is disposed on the electronic element via a thermal interface material, and the supporting portion is bonded to the first side of the carrier and surrounds the electronic element.

10. The electronic package of claim 8, wherein a heat dissipating hole is formed at the body portion of the heat dissipating member, and a position of the heat dissipating hole of the heat dissipating member is corresponded with a position of the heat dissipating accelerator.

11. The electronic package of claim 10, wherein a distribution area of the heat dissipating hole is larger than a distribution area of the heat dissipating accelerator.

12. The electronic package of claim 1, further comprising: a plurality of conductive elements disposed on the second side of the carrier, wherein a part of the plurality of the conductive elements is used to transmit electronic signal and the other part of the plurality of the conductive elements is used to transfer heat.
